(19) United States
(12) Patent Application Publication
(10) Pub. No.: US 2026/0023329 A1
(43) Pub. Date: Jan. 22, 2026

(54) METHOD OF DETERMINATION OF OPTICAL PROPERTIES OF AN OPTICAL SYSTEM

(71) Applicant: Carl Zeiss SMT GmbH, Oberkochen (DE)

(72) Inventors: Pavel RAMIREZ HERNANDEZ, Utrecht (NL); John Godefriedus Louisa VAN DIJK, Eindhoven (NL); Johannes Jacobus Matheus BASELMANS, Oirschot (NL); Bartolomeus Petrus RIJPERS, Nuenen (NL); Leon Pieter Paul SAANEN, Eindhoven (NL); Leon VAN KOUWEN, Schalkwijk (NL)

(21) Appl. No.: 19/345,484

(22) Filed: Sep. 30, 2025

Related U.S. Application Data
(63) Continuation of application No. PCT/EP2024/059574, filed on Apr. 9, 2024.

(30) Foreign Application Priority Data
Apr. 12, 2023 (DE) 10 2023 203 312.7

(51) Int. Cl. G03F 7/00

(52) U.S. Cl. CPC G03F 7/70591; G03F 7/70116

(57) ABSTRACT

A method of determining optical properties of an optical system having an illumination system to illuminate an object field and a projection system to image the object field into an image field, comprises: providing an illumination of the object field via an illumination pupil comprising a plurality of pupil spots; providing an optical element with an optical surface comprising a plurality of shifting optical areas which effect an individual direction shift, depending on the respective shifting optical area, of an illumination beam entering the respective shifting optical area; calibrating the individual direction shift by measuring a pupil spot shift resulting from the shifting optical areas via a measuring pupil in the illumination beam path after the optical element for each of the pupil spots for a plurality of separate field points within the object field; and calculating the optical properties to be determined from the measured pupil spot shift.

### CROSS-REFERENCE TO RELATED APPLICATIONS

The present application is a continuation of, and claims benefit under 35 USC 120 to, international application No. PCT/EP2024/059574, filed Apr. 9, 2024, which claims benefit under 35 USC 119 of German Application No. 10 2023 203 312.7, filed Apr. 12, 2023. The entire disclosure of each of these applications is incorporated by reference herein.

### FIELD

The disclosure relates to a method of determination of optical properties of an optical system. Further, the disclosure relates to an optical apparatus having an optical system comprising an illumination system and a projection system.

### BACKGROUND

A method determining apodisation properties of an optical system is known from US 2013/0271636 A1.

### SUMMARY

The disclosure seeks to develop a method of determinating optical properties in order to be robust in obtaining a proper result of the optical properties to be determined.

In an aspect, the disclosure provides a method of determining optical properties of an optical system comprising an illumination system to illuminate an object field and a projection system to image the object field into an image field. The method comprises the following steps: providing an illumination of the object field via an illumination pupil comprising a plurality of pupil spots; providing an optical element with an optical surface comprising a plurality of shifting optical areas which effect an individual direction shift, depending on the respective shifting optical area, of an illumination beam entering the respective shifting optical area; calibrating the individual direction shift by measuring a pupil spot shift resulting from the shifting optical areas via a measuring pupil in the illumination beam path after the optical element for each of the pupil spots for a plurality of separate field points within the object field; and calculating the optical properties to be determined from a measurement using the calibrated individual direction shift.

Calibrating an individual direction shift which is effected by the plurality of shifting optical areas of the optical element by the help of an illumination pupil comprising a plurality of pupil spots can give an information basis for the later calculation of the optical properties which includes for example information regarding inhomogeneities of a desired individual direction shift of the respective shifting optical areas. Production tolerances regarding the optical element, and for example regarding the shifting optical areas of the optical element, then can be evaluated and compensated for during the determination method and for example based on information obtained in the calculation step. After having obtained potential deviations of the individual direction shifts of the plurality of shifting optical areas from desired values, further steps of an optical properties determination method, which are known but which are now used with the calibrated direction shift data, can be used.

Using the method including the calibration, it is possible to measure the pupil shift properties directly and thus enables during the calculation to decouple projection system effects from illumination system effects on the optical property to be determined.

For example, a selected optical property of the illumination system and/or of the projection system of the optical system can be determined.

An example for the optical property to be determined is the apodisation of the optical system. A further optical property which can be determined via the method is a diattenuation of the optical system.

The calculation step may use a measurement with a full pupil after the calibration step. Such measurement with full pupil may not use a pupil with a plurality of pupil spots, but a homogeneously or continuously illuminated pupil. Alternatively, a measurement with full pupil may use a plurality of separate pupil spots.

The optical element may have at least two shifting optical areas.

The calibration step may be repeated after a given time span. This may minimize an undesired impact with respect for example to the effect of the optical element on the illumination beam due to drift or due to comparable effects.

The calibration of the individual direction shift may be done pupil spot dependent.

Calibrating the individual direction shift can reduce errors stemming from manufacturing errors of the shifting optical areas and for example from manufacturing tolerances. Further, errors can be reduced which stem from a drift of the shifting effect of the shifting optical areas over time. Further, placement errors of the optical element may be reduced. Further, bending errors of the optical element may be reduced.

Using the illumination pupil with the plurality of pupil spots during the calibration step can enable a measurement of deviation stemming from such manufacturing/placement/drift errors.

With the calibration of the individual direction shift, a translational deviation of a respective pupil spot from a given value as well as an azimuthal angular displacement of the respective pupil spot can be calibrated.

During the calibration and calculating step of the method, an angle displacement of each pupil spot from the shifting optical areas may be analyzed, stored, and used within the method. Detection and localization of the respectively shifted pupil spot shifts may be done via fit algorithms like “local maximum”, Gaussian or Lorentzian fit.

Regarding the determination of the apodisation, it is, for example, possible to separate apodisation effects of the illumination system from those of the projection system in order to achieve tight apodisation tolerances independently for the illumination system on the one hand and for the projection system on the other.

The optical element with a plurality of shifting optical areas may be inserted into the beam path between the illumination system and the projection system of the optical system. The plurality of shifting optical areas can then introduce in the projection system a defined new set of illumination angles which differs from the initial set defined by the plurality of pupils. With this new set of illumination angles, access to optical properties of the projection system, for example to the apodisation properties, independent from those of the illumination system is given.

The optical element may be designed to be inserted into the beam path of the optical system in at least two different orientations. This can reduce the number of shifting types of the shifting optical areas.

The optical element can comprise at least one non-shifting optical area which does not impose a direction shift of an illumination beam entering such non-shifting optical area, wherein a reference illumination beam entering the non-shifting optical area also is measured during the calibrating step. Such non-shifting optical areas can further improve the quality of the calibrating step of the method. The non-shifting optical areas may be embodied as pinholes in the optical element.

The optical element can comprise as the shifting optical areas a plurality of wedges with different wedge orientations. Such wedges as the shifting optical areas have proven to be effective in an apodisation properties determination method. In that respect, it is referred to US 2013/0271636 A1. A tilt of the wedges may be in the range of 10 mrad to 55 mrad. Such tilt may be measured with respect to a plane perpendicular to an optical axis of the optical system. The wedge tilt may be selected such that after a respective direction shift, the illumination beam subjected to such direction shift still is in the further beam path of the optical system within its numerical aperture. Depending on the accuracy of a measurement system to measure the respective pupil spot shift, also which tilt angles smaller than 10 mrad are possible. In case, the numerical aperture of the optical system is large enough, also wedge tilt angles larger than 55 mrad are possible.

As an alternative or in addition to a shifting via wedges, such shifting also is possible using a grating, for example a linear grating. Such linear grating may be moved transversely, i.e., perpendicular to a path of the illumination scheme. Such translational movement may be stepwise and also is referred to as shearing movement.

An angle between the different adjacent orientations of the wedges differs from an integer multiple of 45°. Such angle differences between the wedge orientations which deviate from certain known rectangular have proven to be useful to determine the apodisation properties. During the calibration step of the method, such deviations can be compensated for.

For example, an angle difference of an integer multiple of 90° gives four different wedge orientations (0°/90°/180°/270°) and respectively four types of wedges. In further embodiments of the optical element, different or additional wedge orientations of 45°, 135°, 225° and/or 315° may be provided. In further examples, the wedges have an orientation of 5°, 10°, 15°, 30°, or 45° with respect to each other. As a result, more than four wedge orientation types may be present, e.g., six types or eight types. Even a larger number of wedge orientation types can be present.

By using an optical element which can be inserted into the beam path of the optical system in at least two orientations, this can reduce the number of wedge orientations involved. For example, a 90° wedge orientation would become a 270° wedge orientation after rotating the whole optical element around 180°.

The plurality of pupil spots of the provided illumination pupil can be arranged as a grid. Such a grid arrangement of the plurality of pupil spots has proven to be effective. Such grid arrangement may be generated via a pupil generating device which may include a pupil facet mirror and/or a pupil microlens array and/or a plurality of pinholes in the pupil plane.

During the calibration step a map can be created in which the respective pupil spot shift is attributed to the respective pupil spot and to the respective field point. Such calibration information map helps to qualify the calibrated optical element which then may be used without the necessity to repeat the calibration step. A measure for the pupil spot shift is the individual direction shift of the respective illumination beam.

The optical element can comprise at least one optical grating area which imposes a diffraction of an illumination beam entering such optical grating area and further passing one of the shifting optical areas of the optical element, wherein the method includes a Ronchi test to obtain the optical property to be determined. Including such a Ronchi test by using a diffraction of the illumination beam via the at least one optical grating area can enable a Ronchi test measurement. A Ronchi test is described in J. Braat et al. “Improved Ronchi test with extended source”, J. Opt. Soc. Am. A, Vol. 16, No. 1, pp. 131-140 (1999). From such Ronchi test measurement, phase, offset and modulation data can be obtained, which further can be used to obtain, e.g., the apodisation properties of the optical system. The optical grating area may be part of the optical element. The respective optical grating area may be attributed to a respective one of the shifting optical areas. A sequence of arrangement of the optical grating area and the optical shifting area along the beam path of the respective illumination beam is dependent on the respective embodiment of the optical apparatus. The optical grating area may follow the optical shifting area or the optical shifting area may follow the optical grating area along such beam path.

The optical system can comprise at least one optical polarizer which imposes a polarization of an illumination beam entering the shifting optical area, an analyzer the optical polarizer being used to determine a transmission of the optical element for two different polarization states of the illumination beam, wherein the method includes measuring such transmission data and from this a diattenuation of the optical system is obtained. Using such an optical polarizer can enable a determination of the diattenuation of the optical system. The optical polarizer may be movable between different polarizer positions imposing different polarisation states on the illumination beam. The optical polarizer may be a linear polarizer. The optical polarizer may be driven by a controlled drive unit for the controlled setting of a given polarisation state.

During the measurement of the transmission data, an additional optical analyzer can be used to determine the transmission of the optical element for two different polarization states of the illumination beam. Use of such an optical analyzer is further helpful, for example for a determination of diattenuation of the optical system.

The disclosure also seeks to improve an optical apparatus capable to perform such optical properties determination method.

In an aspect, the disclosure provides an optical apparatus having an optical system comprising an illumination system to illuminate an object field and a projection system to image the object field into an image field. The optical apparatus comprises: a light source for generating an illumination beam to illuminate the object field via the illumination system; a pupil generating device as part of the illumination system to provide an illumination of the object field via an illumination pupil comprising a plurality of pupil spots; an optical element with an optical surface comprising a plurality of shifting optical areas which effect an individual directing shift, depending on the respective shifting optical area of the illumination beam entering the respective shifting optical area; and a sensor device to measure a pupil spot shift resulting from the different shifting optical areas via a measuring pupil in the illumination beam path after the optical element for each of the pupil spots for a plurality of separate field points within the object field.

Features of such optical apparatus correspond to those of the optical properties determination method explained above. For example, the optical apparatus can be designed to perform such method.

The optical apparatus can include a calibration module to calibrate the individual direction shift, the calibration module being in signal connection with the sensor device. Such an optical apparatus allows an automatic calibrating step according to the method discussed above.

The optical apparatus can include a module to calculate optical properties of the optical system from pupil measurement data using the calibrated individual direction shift, the module being in signal connection with the sensor device and the calibration module. Such an optical apparatus having a calculation module enables an automatic calculating step within the method discussed above.

The optical apparatus can include a Ronchi grating as part of the optical element. Use of a Ronchi grating as part of the respective optical grating area during the method gives the advantages mentioned herewith.

The optical apparatus can include an optical polarizer to polarize an illumination beam entering the optical element. The optical apparatus can include an optical analyzer to determine a transmission of the optical element for two different polarisation states of the illumination beam. Use of such optical polarizers can provide corresponding features noted above.

### BRIEF DESCRIPTION OF THE DRAWINGS

Exemplary embodiments of the disclosure are described hereinafter by help of the enclosed figures:

FIG. 1 shows a lithographic apparatus including an optical apparatus having an optical system comprising an illumination system to illuminate an optic field and a projection system to image the optic field into an image field, the optical apparatus being capable to determine optical properties of the optical system;

FIG. 2 shows schematically variants of a beam path through the optical apparatus;

FIG. 3 shows a top view of an optical element having an optical surface comprising a plurality of wedges and a further plurality of pinholes being part of the optical apparatus, the optical element being used in a method of determination of optical properties of the optical system;

FIG. 4 shows a cross section of one of the wedges of the optical element of FIG. 3 and further depicts a beam path of an individual ray through the wedge resulting in a ray direction shift, wherein also a part of a substrate of the optical element is shown carrying the wedge;

FIG. 5 another embodiment of a wedge on a substrate of the optical element wherein the wedge is fixed on the substrate via an adhesive structure;

FIGS. 6 to 8 in a top view different embodiments of adhesive structures which can be used to adhere the wedge according to FIG. 5 to the substrate;

FIG. 9 a perspective view of another embodiment of one of the wedges of the optical element;

FIG. 10 an intensity distribution of illumination light via an illumination pupil comprising a plurality of pupil spots arranged as a grid within the circular pupil, the illumination pupil being used in the method of determination of optical properties of the optical system;

FIG. 11 the result of a measurement of a pupil spot shift resulting from an illumination of the optical element with a pupil intensity distribution according to FIG. 10, wherein possible pupil spot shifts are indicated attributed to the respective pupil spot positions;

FIG. 12 magnified the different pupil spot shift possibilities introduced by the different kind of wedges on the optical element;

FIG. 13 in a view similar to FIG. 2 a further arrangement of the optical apparatus being capable to determine the attenuation properties of the optical system;

FIG. 14 schematically components guiding a beam path through another embodiment of the optical apparatus including further a Ronchi grating as part of an apparatus to determine optical properties of the optical system;

FIG. 15 in a view similar to FIG. 14 a diffraction scheme of the Ronchi grating embodiment of FIG. 14;

FIGS. 16 to 18 positional relationships between linear grating (source grating) structures of the gratings according to FIGS. 14 and 15 on the one hand, and of a Ronchi grating in the shape of a checker board arrangement of a sensor device showing a first shear direction x caused by different translation positions of the linear grating relative to the Ronchi grating along the first shear direction x;

FIGS. 19 to 21 similar to FIGS. 16 to 18, positional relationships between a Ronchi grating of a further embodiment of an optical element according to FIGS. 14 and 15 with different linear grating structure orientation, shown for three positional relationships along another shear direction y; and

FIG. 22 in a diagram a phase signal measured by one pixel of the sensor device in the relative positions according to one of FIGS. 16 to 18 and/or 19 to 21.

### DETAILED DESCRIPTION

This specification discloses one or more embodiments that incorporate various features of this disclosure. The disclosed embodiment(s) merely exemplify the present disclosure. The scope of the present disclosure is not limited to the disclosed embodiment(s).

The embodiment(s) described, and references in the specification to “one embodiment”, “an embodiment”, “an example embodiment”, etc., indicate that the embodiment(s) described may include a particular feature, structure, or characteristic, but every embodiment may not necessarily include the particular feature, structure, or characteristic. Moreover, such phrases are not necessarily referring to the same embodiment. Further, when a particular feature, structure, or characteristic is described in connection with an embodiment, it is understood that it is within the knowledge of one skilled in the art to effect such feature, structure, or characteristic in connection with other embodiments whether or not explicitly described.

Embodiments of the present disclosure may be implemented in hardware, firmware, software, or any combination thereof. Embodiments of the present disclosure may also be implemented as instructions stored on a machine-readable medium, which may be read and executed by one or more processors. A machine-readable medium may include any mechanism for storing or transmitting information in a form readable by a machine (e.g., a computing device). For example, a machine-readable medium may include read only memory (ROM); random access memory (RAM); magnetic disk storage media; optical storage media; flash memory devices; electrical, optical, acoustical or other forms of propagated signals (e.g., carrier waves, infrared signals, digital signals, etc.), and others. Further, firmware, software, routines, instructions may be described herein as performing certain actions. However, it should be appreciated that such descriptions are merely for convenience and that such actions in fact result from computing devices, processors, controllers, or other devices executing the firmware, software, routines, instructions, etc. Before describing embodiments in more detail, however, it is instructive to present an example environment in which embodiments of the present disclosure may be implemented.

Although specific reference may be made in this text to the use of lithographic apparatus in the manufacture of ICs, it should be understood that the lithographic apparatus described herein may have other applications, such as the manufacture of integrated optical systems, guidance and detection patterns for magnetic domain memories, liquid-crystal displays (LCDs), thin film magnetic heads, etc. The skilled artisan will appreciate that, in the context of such alternative applications, any use of the terms “wafer” or “die” herein may be considered as synonymous with the more general terms “substrate” or “target portion”, respectively. The substrate referred to herein may be processed, before or after exposure, in for example a track (a tool that typically applies a layer of resist to a substrate and develops the exposed resist) or a metrology or inspection tool. Where applicable, the disclosure herein may be applied to such and other substrate processing tools. Further, the substrate may be processed more than once, for example in order to create a multi-layer IC, so that the term substrate used herein may also refer to a substrate that already contains multiple processed layers.

The terms “radiation” and “beam” used herein encompass all types of electromagnetic radiation, including ultraviolet (UV) radiation (e.g., having a wavelength of 365, 248, 193, 157 or 126 nm) and extreme ultra-violet (EUV) radiation (e.g., having a wavelength in the range of 5-20 nm), as well as particle beams, such as ion beams or electron beams.

The term “patterning device” used herein should be broadly interpreted as referring to a device that can be used to impart a radiation beam with a pattern in its cross-section such as to create a pattern in a target portion of the substrate. It should be noted that the pattern imparted to the radiation beam may not exactly correspond to the desired pattern in the target portion of the substrate. Generally, the pattern imparted to the radiation beam will correspond to a particular functional layer in a device being created in the target portion, such as an integrated circuit.

A patterning device may be transmissive or reflective. Examples of patterning device include masks, programmable mirror arrays, and programmable LCD panels. Masks are well known in lithography, and include mask types such as binary, alternating phase-shift, and attenuated phase-shift, as well as various hybrid mask types. An example of a programmable mirror array employs a matrix arrangement of small mirrors, each of which can be individually tilted so as to reflect an incoming radiation beam in different directions; in this manner, the reflected beam is patterned.

The support structure holds the patterning device. It holds the patterning device in a way depending on the orientation of the patterning device, the design of the lithographic apparatus, and other conditions, such as for example whether or not the patterning device is held in a vacuum environment. The support can use mechanical clamping, vacuum, or other clamping techniques, for example electrostatic clamping under vacuum conditions. The support structure may be a frame or a table, for example, which may be fixed or movable as desired and which may ensure that the patterning device is at a desired position, for example with respect to the projection system. Any use of the terms “reticle” or “mask” herein may be considered synonymous with the more general term “patterning device”.

The term “projection system” used herein should be broadly interpreted as encompassing various types of projection system, including refractive optical systems, reflective optical systems, and catadioptric optical systems, as appropriate for example for the exposure radiation being used, or for other factors such as the use of an immersion fluid or the use of a vacuum. Any use of the term “projection lens” herein may be considered as synonymous with the more general term “projection system”.

The illumination system or illuminator may also encompass various types of optical components, including refractive, reflective, and catadioptric optical components for directing, shaping, or controlling the beam of radiation, and such components may also be referred to below, collectively or singularly, as a “lens”.

The lithographic apparatus may be of a type having two (dual stage) or more substrate tables (and/or two or more support structures). In such “multiple stage” machines the additional tables may be used in parallel, or preparatory steps may be carried out on one or more tables while one or more other tables are being used for exposure.

The lithographic apparatus may also be of a type wherein the substrate is immersed in a liquid having a relatively high refractive index, e.g., water, so as to fill a space between the final element of the projection system and the substrate. Immersion techniques are well known in the art for increasing the numerical aperture of projection systems.

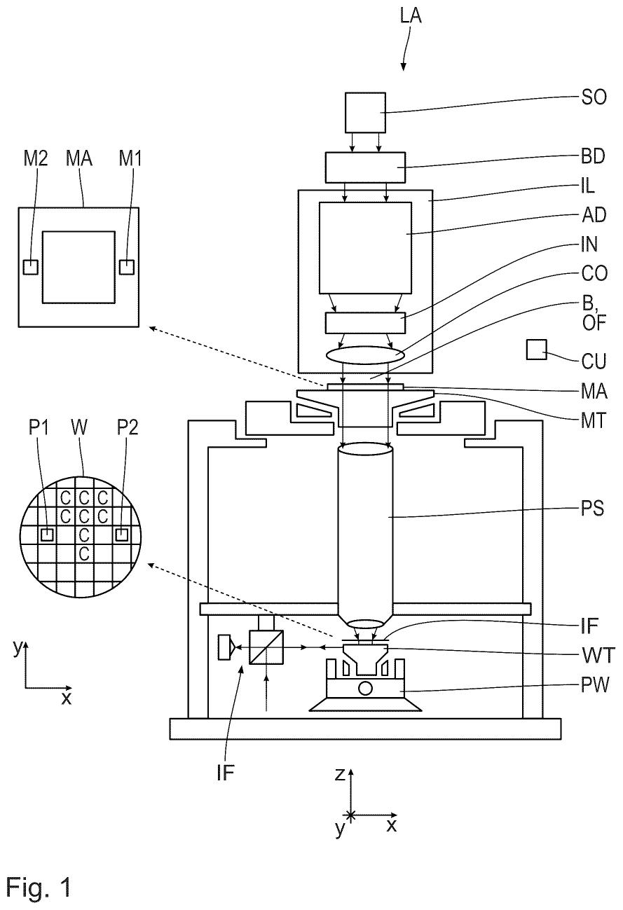

FIG. 1 schematically illustrates a lithographic apparatus LA according to an embodiment of the present disclosure. The apparatus includes an illumination system IL adapted to condition a beam B of radiation (e.g., UV radiation) and a support structure such as a mask table MT configured to hold a patterning device such as a mask MA and connected to a first positioning device PM configured to accurately position the patterning device with respect to a projection system PS. The projection system PS is adapted to image a pattern imparted to the beam B by the patterning device MA in an object field OF of the projection system PS onto a target portion C of a substrate W located in an image field IF. The apparatus also includes a substrate table such as a wafer table WT configured to hold the substrate W such as a resist coated wafer and connected to a second positioning device PW configured to accurately position the substrate with respect to the projection system PS.

The illumination system may include various types of optical components, such as refractive, reflective, magnetic, electromagnetic, electrostatic or other types of optical components, or any combination thereof, for directing, shaping, or controlling radiation.

The support structure MT holds the patterning device MA in a manner that depends on the orientation of the patterning device, the design of the lithographic apparatus, and other conditions, such as for example whether or not the patterning device is held in a vacuum environment. The support structure can use mechanical, vacuum, electrostatic or other clamping techniques to hold the patterning device. The support structure may be a frame or a table, for example, which may be fixed or movable as desired. The support structure may ensure that the patterning device is at a desired position, for example with respect to the projection system.

The term “patterning device” should be broadly interpreted as referring to any device that can be used to impart a radiation beam with a pattern in its cross-section such as to create a pattern in a target portion of the substrate. The pattern imparted to the radiation beam may correspond to a particular functional layer in a device being created in the target portion, such as an integrated circuit.

The patterning device may be transmissive or reflective. Examples of patterning devices include masks, programmable mirror arrays, and programmable LCD panels. Masks are well known in lithography, and include mask types such as binary, alternating phase-shift, and attenuated phase-shift, as well as various hybrid mask types. An example of a programmable mirror array employs a matrix arrangement of small mirrors, each of which can be individually tilted so as to reflect an incoming radiation beam in different directions. The tilted mirrors impart a pattern in a radiation beam which is reflected by the mirror matrix.

The projection system, like the illumination system, may include various types of optical components, such as refractive, reflective, magnetic, electromagnetic, electrostatic or other types of optical components, or any combination thereof, as appropriate for the exposure radiation being used, or for other factors such as the use of a vacuum. It may be desired to use a vacuum for EUV radiation since gases may absorb too much radiation. A vacuum environment may therefore be provided to the whole beam path with the aid of a vacuum wall and vacuum pumps. Some gas may be provided in some parts of the lithographic apparatus, for example to allow gas flow to be used to reduce the likelihood of contamination reaching optical components of the lithographic apparatus.

As depicted in FIG. 1 the apparatus is of a transmissive type employing a transmissive mask MA. Alternatively, the apparatus could be of a reflective type employing a programmable mirror array.

The illuminator IL receives a beam of radiation from a radiation source SO. The illuminator IL comprises an adjustment device AD configured to set an outer and/or inner radial extent, an integrator IN and a condenser CO. The source SO will include at least one laser, e.g. one or two UV excimer lasers. For convenience of illustration in FIG. 1 a single source SO is shown and the source SO may comprise both lasers or alternatively multiple sources SO may be provided each with a single laser the beams of which are combined before or after entering the projection system PS. Also provided is a beam delivery system BD including for example suitable directing mirrors and/or a beam expander. The sources SO and the beam delivery system BD combine to form a radiation system that presents a suitable beam of radiation to the projection system. It will be understood that this beam of radiation B comprises radiation from at least one laser. It will also be understood that the beam may comprises alternating pulses of radiation from the at least one laser.

The projection system PS may include a diaphragm with an adjustable clear aperture used to set the numerical aperture of the projection system PS at wafer level at a selected value.

The beam of radiation B is incident on the patterning device MA which is held on the support structure MT. Having traversed the patterning device, the beam of radiation B passes through the projection system PS which focuses the beam onto a target portion C of the substrate W. With the aid of a second positioning device PW and position sensor

IF (e.g. an interferometric device) the substrate table WT can be moved accurately so as to position different target portions C in the path of the beam B. Similarly, the first positioning device PM and another position sensor together with alignments marks M 1, M 2 and P 1 and P 2 can be used to accurately position the patterning device MA with respect to the path of the beam B and substrate W. In general, movement of the support structure MT and the substrate table WT will be realized with the aid of a long-stroke module for coarse poisoning and a short-stroke module for fine positioning. However, in the case of a stepper (as opposed to a scanner) the support structure may be connected to a short stroke actuator only or may be fixed.

The depicted apparatus could be used in at least one of the following modes:
1. In step mode, the support structure (e.g., mask table) MT and the substrate table WT are kept substantially stationary, while an entire pattern imparted to the radiation beam is projected onto a target portion C at one time (i.e., a single static exposure). The substrate table WT is then shifted in the X and/or Y direction so that a different target portion C can be exposed.
2. In scan mode, the support structure (e.g., mask table) MT and the substrate table WT are scanned synchronously while a pattern imparted to the radiation beam is projected onto a target portion C (i.e., a single dynamic exposure). The velocity and direction of the substrate table WT relative to the support structure (e.g., mask table) MT may be determined by the (de-) magnification and image reversal characteristics of the projection system PS.
3. In another mode, the support structure (e.g., mask table) MT is kept substantially stationary holding a programmable patterning device, and the substrate table WT is moved or scanned while a pattern imparted to the radiation beam is projected onto a target portion C. In this mode, generally a pulsed radiation source is employed and the programmable patterning device is updated as desired after each movement of the substrate table WT or in between successive radiation pulses during a scan. This mode of operation can be readily applied to maskless lithography that utilizes programmable patterning device, such as a programmable mirror array of a type as referred to above.

Combinations and/or variations on the above described modes of use or entirely different modes of use may also be employed. A known problem with conventional apparatus is the problem of apodisation as the beam paths through the projection system PL. Apodisation is a known optical phenomenon which may result in an angular intensity distribution of a light beam which is non-uniform and for example where the intensity falls away at the edges of the beam. Apodisation may be caused by a change of an illumination intensity distribution caused by lens materials or lens properties of lenses of the optical apparatus. Lens apodisation is becoming increasingly desirable particularly for example in systems that use a complementary phase shift mask. Such a mask is typically illuminated by a coherent light beam with the light being concentrated around the optical axis of the system. The diffracted light will not contain a zero order beam and will be more directed towards the edge of the aperture of the system. The separation between these diffracted beams (and thus the distance to the optical axis) is proportional to the resolution of the feature being imaged. Apodisation can lead to a similar dose error dependent on the resolution of the lines being imaged. It is desirable therefore to be able to measure lens apodisation and differences in lens apodisation both in one apparatus where there may be drift over time and between systems.

In order to measure apodisation accurately it is desirable to know the light distribution at the reticle level in order to compare this with the light distribution at the wafer level. Currently in known apodisation determination techniques the light distribution at the reticle level is assumed (for example) to have a uniform distribution, but this is not necessarily the case. One solution to this may be to directly measure the light distribution at the reticle level but this may not be possible or easy. The present disclosure at least in some embodiments presents an alternative solution in which multiple shifted copies of the same light distribution are measured with different parts of the lens.

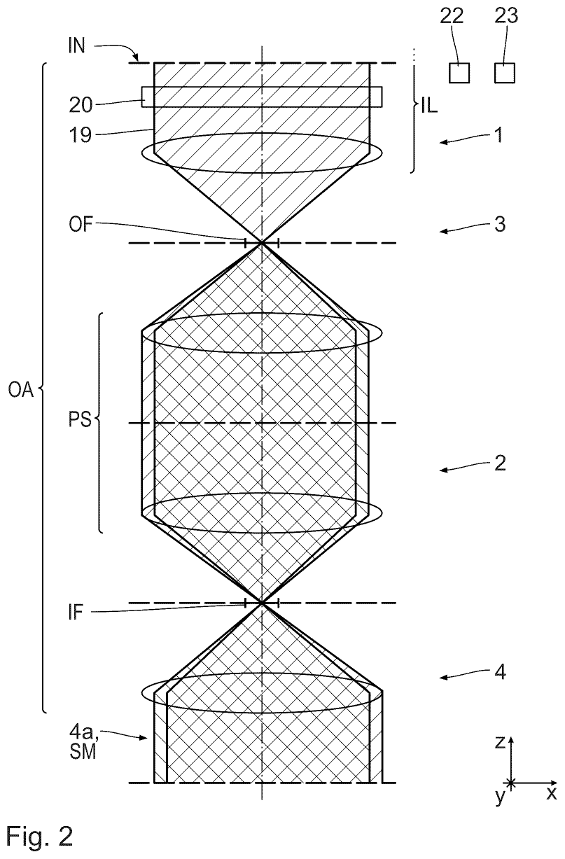

FIG. 2 shows schematically the basic idea behind apodisation measurements. In that respect, it also is referred to US 2013/0271636 A1. In addition to an apodisation measurement, with the optical apparatus described herein after, a determination of further optical properties of an optical system of such optical apparatus is possible. Examples for such further optical properties include a diattenuation of the optical system.

FIG. 2 illustrates an illumination pupil 1 of the illumination system IL and a projection pupil 2 the projection system PS. The illumination system IL and the projection system PS constitute an optical system of the projection exposure apparatus shown in FIG. 1.

An optical element (e.g., a reticle, a mask, or an original) 3 is placed between the illumination pupil 1 of the illumination system IL and the projection pupil 2 of the projection system with the optical element 3 being generally located in the focal plane of the illumination system IL. In other words, the optical element 3 is located in the object plane at the object field OF where in use the mask MA would be located. The optical element 3 comprises a coating layer, for example a chromium layer, a plurality of pinholes arranged in the coating layer, such that radiation can pass through the optical element 3 via the pinholes, and a plurality of sub-elements (wedges 5) to shift the radiation. Those sub-elements also are denoted as shifting optical areas. An unshifted beam path is depicted with a first hatching. A shifted beam path is depicted with a second, different hatching.

Below the projection system PS is provided a sensor device 4a comprising a sensor module SM including a camera having camera pupil 4. A pinhole for measuring of the camera pupil 4 is located in generally the same plane as the substrate W would be located in use, i.e., in an image plane at the image field IF of the projection system PS. The camera of the sensor device 4a may be placed in a far field plane without imaging optics or may be located in a pupil plane with imaging optics.

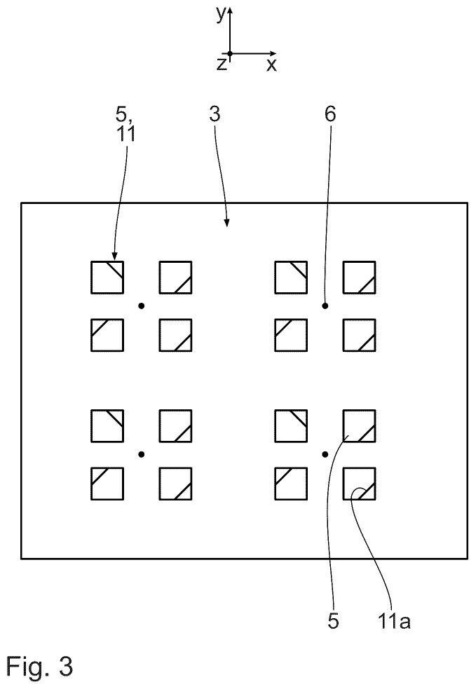

FIG. 3 shows in more detail the structure of the optical element 3. The optical element 3 comprises an array of optical wedges 5 and pinholes 6 disposed in a regular array in the x and y directions. Each wedge 5 is disposed on a substrate 3a of the optical element 3. The pinholes 6 located between the wedges 5 can be used as a reference. Pinholes are also provided underneath each wedge 5, not illustrated in FIG. 3, such that radiation impinging the optical element 3 can pass toward the projection system PS. Those pinholes below the wedges 5 are indicated by an exemplified pinhole “x” in FIG. 5.

The pinholes 6 are provided in the coating layer at a surface of the optical element 3. The coating may be for example a chromium layer. In addition, other reticle features, e.g., grating structures, may be provided on the or in lieu of the coating layer. Also these other reticle features may be located beneath the wedges 5.

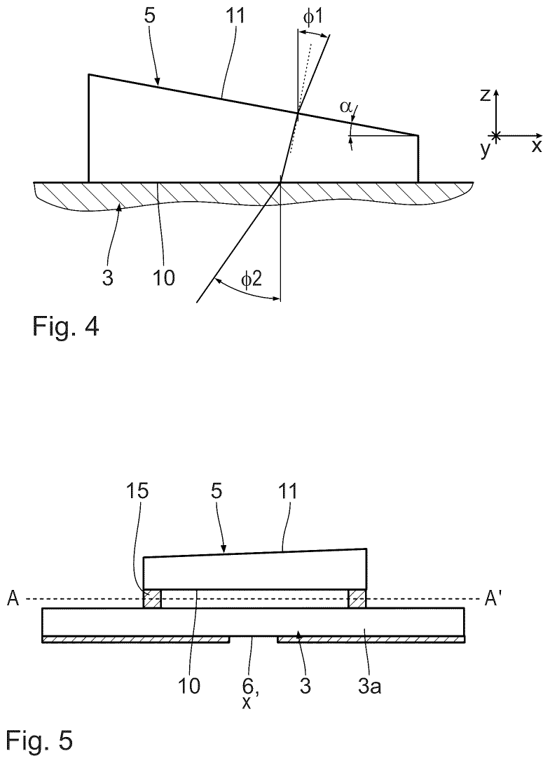

A more detailed illustration of a wedge 5 is illustrated in FIG. 4 which also shows schematically a part of the substrate 3a of the optical element 3. The wedge 5 is arranged at a surface of the optical element 3, with the first surface 10 facing the substrate 3a of the optical element 3. A second surface 11 of the wedge 5, opposite to the first surface 10, is inclined with an angle α. A radiation beam impinging the second surface 11 will experience a direction change Φ₂-Φ₁ as a function of the wedge tilt angle α, when the radiation beam exits the wedge 5 at the first surface 10. The plane in which the inclination or tilt angle α is measured represents a wedge orientation of the respective wedge 5 with respect to a reference plane. In the embodiment of FIG. 4, such tilt angle reference plane is the xz-plane and the inclination of the respective wedge 5 thus is in the positive x-direction. The location and orientation of the respective tilt angle reference plane hereinafter also is referred to as a wedge orientation.

In order to fixate the sub-elements (wedges) 5 to the surface of the optical element 3, the sub-elements 5 can be clamped by a clamping mechanism arranged at the surface.

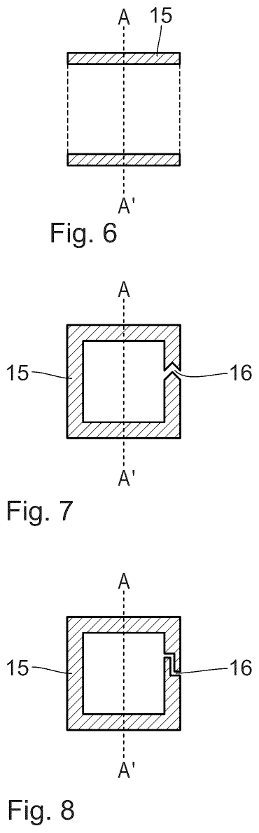

Fixation of the sub-elements 5 may alternatively or in addition be done by adhesives 15 provided between the sub-elements 5 and the surface of the optical element 3, as illustrated by the embodiments shown in FIGS. 6 to 8.

The adhesive 15 can be provided at the periphery (edge area) of the sub-element 5 outside the optical path. Herewith, the adhesive 15 does not interact with radiation, for example, used for the apodisation measurement. With adhesives 15 provided at the edge area, the adhesive forms a spacer. Hence, a partly closed spaces between the sub-elements 5 and the substrate 3a of the optical element 3 are formed.

When, for example, two parallel spacers 15 are provided (see FIG. 6) or spacers are provided at the four corners, there is a risk of having unwanted contamination trapped underneath the sub-elements 5 (for instance dust particles), especially at the pinhole underneath the wedge 5.

Using adhesives 15 at additional edge areas for the fixation of the sub-elements may reduce the chance of particles trapped between the sub-elements 5 and the optical element 3. For example, adhesives may be provided at three edge areas or at four edge areas, FIGS. 7 and 8.

With four edge areas provided with adhesives 15 (or spacers) a closed space may be formed. Such a configuration may not be desirable in case the optical element 3 and therefore also the sub-elements 5 are subjected to pressure changes. Pressure changes may occur during a loading sequence in the lithographic apparatus LA, for example, when the local environment is vacuumized. Pressure differences between the closed space and the local environment may cause stress to the spacers 15 and or the sub-element 5. To control the pressure in the space underneath the sub-element 5 and to prevent dust particles entering this space, venting ports 16 may be provided in at least one of the spacers, as illustrated by FIGS. 7 and 8. The venting ports, forming a labyrinth seal 16, allows a gas flow between the closed space and the local environment, but prevents dust particles to enter the closed space. The venting ports 16 may be considered to be physically open but optically closed.

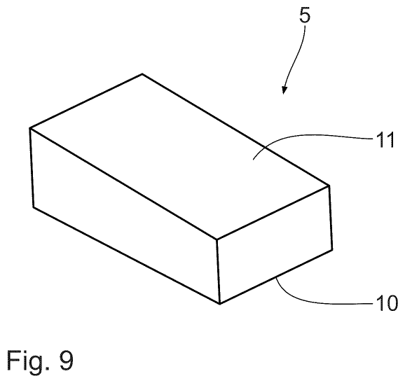

FIG. 9 shows a perspective view of an exemplary embodiment of one of the wedges 5. FIG. 3 indicates that the wedged second surface 11 of the respective wedge 5 facing to viewer of FIG. 3 may be inclined in four principal directions, i.e., may be inclined in positive or negative x-direction or in positive or negative y-direction. Further, an inclination also along the bisecting lines between the +/−x and the +/−y coordinates are possible, which is indicated via the diagonal inclination qualifying lines 11a in FIG. 3.

A pupil generating device 20 which is schematically shown in FIG. 2 is located within the integrator IN of the illumination system IL. The pupil generating device 20 is located in the beam path of illumination light 19 upstream the illumination pupil 1. Such pupil generating device 20 may include a field facet mirror and a pupil facet mirror with each pupil facet of the pupil facet mirror being capable to define a pupil spot within the illumination pupil 1. For example, when using illumination light wavelengths which are not in the EUV range but are in the DUV range, such pupil generating device may have another configuration known in the art, for example including at least one microlens array.

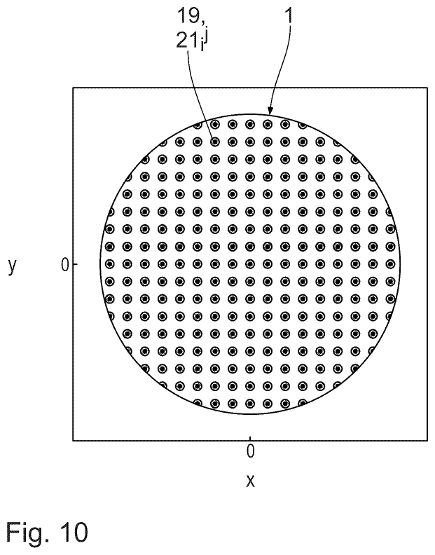

FIG. 10 shows an example for an intensity distribution of the illumination light 19 over the illumination pupil 1. Such intensity distribution of the illumination pupil 1 comprises a plurality of pupil spots 21ᵢ^{j} arranged as a grid having i rows and j columns. The number i of the rows on the one hand and j of the columns on the other of such grid arrangement may be in the range between 1 and 500, e.g., in the range between 10 and 50. In the shown embodiment, these numbers i and j approximate 20, respectively. The illumination pupil 1 has at least two separate pupil spots 21. By using a sequence of measurements with different pupil spots, also a single pupil spot 21 may be used during a single measurement step of such sequence.

In case of a pupil facet mirror or a microlens array design of the pupil generating device 20, each of the pupil spots 21ᵢ^{j} may be produced via exactly one pupil facet or via exactly one microlens. As a further alternative, the pupil generating device 20 may comprise a plurality of pinholes in the plane of the illumination pupil 1.

The optical system including the illumination system IL and the projection system PS, the source SO, the pupil generating device 20, the optical element 3 and the sensor device 4a are part of an optical apparatus to determine the apodisation properties of the optical system.

Further parts of this optical apparatus OA (compare FIG. 2) are a calibration module 22 and a calculation module 23.

The calibration module 22 serves to calibrate an individual direction shift Φ₂-Φ₁ of the respective wedges or shifting optical areas 5 as in more detail is explained below. The calibration module 22 is in signal connection with the sensor device 4a.

The calculation module 23 serves to calculate the apodisation properties of the optical system from a measured pupil spot shift which results from the shifting optical areas, i.e., the wedges 5 of the optical element 3 as also is in more detail explained below. The calculation module 23 is in signal connection with the sensor device 4a and the calibration module 22.

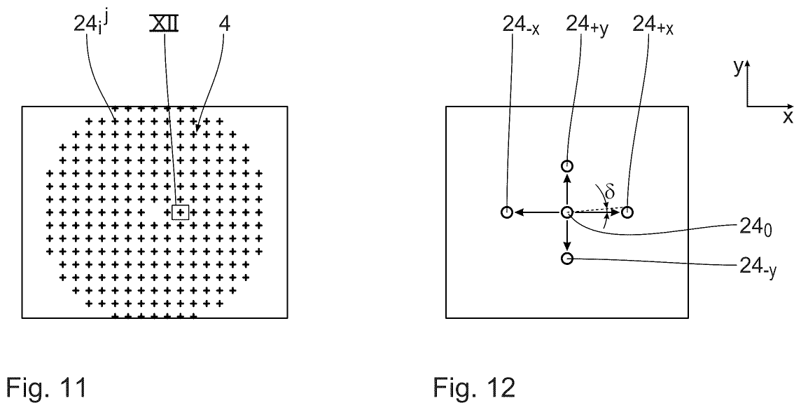

FIGS. 11 and 12 show exemplified possible pupil spot shifts which may be introduced by the wedges 5 of the optical element 3 to the pupil spots 21ᵢ^{j} and can be measured via the sensor device 4a, for example for a plurality of separate field points.

Each of a plurality of measuring spots 24ᵢ^{j} represents a measurement of an intensity of one of the pupil spots 21ᵢ^{j} with the sensor device 4a after having experienced a pupil spot shift by interaction with the shifting optical area, i.e., the perspective wedge 5 of the optical element 3.

Dependent on the respective inclination orientation of the inclined wedge surface 11 of the wedge 5, four different shift directions of the pupil spot shift are possible which are shown enlarged in FIG. 12. An initial, unshifted position 24₀ is indicated by a measurement spot 24ᵢ^{j} of a pupil spot 21ᵢ^{j} experiencing no pupil spot shift. Such unshifted measurement spot 24₀ e.g. results from a pupil spot 21ᵢ^{j} passing the optical element 3 via one of the pinholes 6.

The four principal pupil spot shift directions further indicated in FIG. 12 are denoted as 24₊ₓ, 24₋ₓ, 24_{+y} and 24_{-y}. Those four principal pupil spot shift directions correspond to the four principal inclination directions of the wedges 5 of the optical element 3.

The optical apparatus OA (compare for example FIG. 2) operates as follows:

Via the source SO and the pupil generating device 20, an illumination of the object field OF the lithographic apparatus LA via the illumination pupil 1 comprising the plurality of pupil spots 21ᵢ^{j} is provided.

Further, the optical element 3 is provided having an optical surface with the plurality of shifting optical areas 5, i.e., the wedges 5.

Via the sensor device 4a and the calibration module 22, the optical apparatus OA calibrates an individual direction shift Φ₂-Φ₁, effected by the respective wedge 5 of the optical element by measuring the pupil spot shift, i.e., by measuring the respective measuring spot 24ᵢ^{j} corresponding to the pupil spot 21ᵢ^{j}. The measuring spots 24ᵢ^{j} are part of the camera pupil 4, i.e., a measuring pupil of the sensor device 4a.

A measure for the pupil spot shift is the individual direction shift Φ₂-Φ₁ of the respective illumination beam as explained above for example with reference to FIG. 4.

This calibrating step is done for a plurality of separate field points within the object field OF the lithographic apparatus LA.

During the calibration step, also reference beams entering the pinholes 6, i.e., entering non-shifting optical areas of the optical element 3, can be measured.

Further, non-shifting optical areas of the optical element 3 may be realized via flat elements, i.e., flat “wedges” having parallel entry and exit optical surfaces. Such flat “wedges” may have the same optical path length as the “real” wedges 5.

After such calibration, the apodisation properties to be determined are calculated from the measured pupil spot shifts.

Due to the calibration step of this determination method, it is possible to compensate direction deviations of the pupil spot shifts 24₊₋ₓ, 24_{+-y} deviating from the principal directions of the coordinates x and y. Such a shift deviation is indicated in FIG. 12 by a dashed arrow with a deviation angle δ.

During the calibration step, a map is created in which the respective pupil spot shift is attributed to the respective pupil spot 21ᵢ^{j} and to the respective field points of the actual measurement.

As an alternative to using optical wedges it may also be possible to use blazed diffraction gratings that are optimized for use at a specific wavelength.

The measurements obtained by the sensor module of light intensity at adjacent points contain data relating to the apodisation difference of two neighbouring parts of the projection system pupil and may be passed to a digital processor which then reconstructs the total apodisation map. This may be done using techniques that are identical to the algorithms used in shearing interferometry where a wavefront difference is measured between displaced copies of the wavefront. From these copies the original wavefront can be reconstructed. See for instance “Optical Shop Testing” (Second Edition) by Daniel Malacara, John Wiley & Sons (1992), which is incorporated by reference herein in its entirety. It will be understood that data from the sensor module will be sent to a processor which may include a computer processor running software implementing the algorithms that are used.

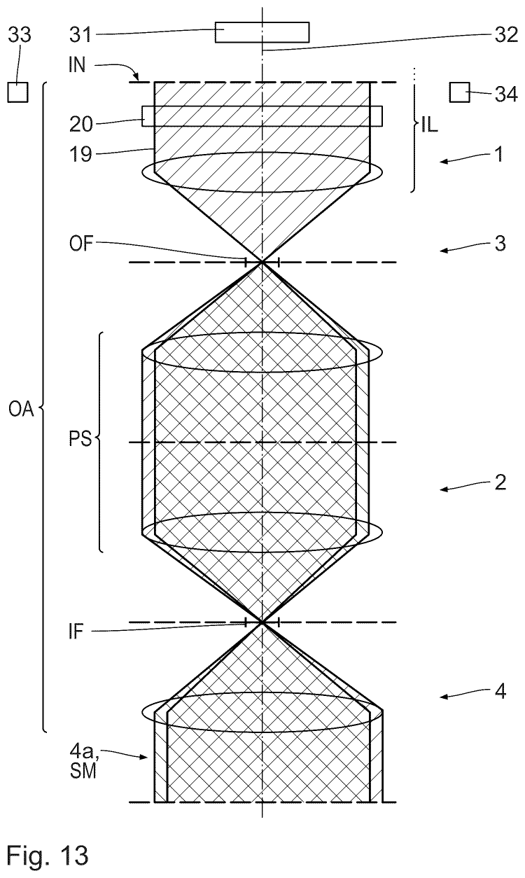

FIG. 13 shows in a depiction similar to that of FIG. 2, another embodiment of an optical apparatus OA including a pupil generating device and an optical element having shifting optical areas and further including a sensor device, as explained above with respect to FIGS. 1 to 12. Components and functions which already have been discussed with respect to these previous figures carry the same reference numerals or reference signs and are not described in detail again.

The optical apparatus OA of FIG. 13 includes an additional optical polarizer 31 which is located in the beam path of the optical apparatus OA upstream of the integrator IN of the illumination system IL.

The optical polarizer 31 is embodied as a linear polarizer. The optical polarizer 31 imposes a polarization of the illumination light 19 in the beam path upstream of the integrator IN. With the polarization state determined by the optical polarizer 31, the illumination light 19 then enters the optical element 3 and the respective wedge 5 resulting in an individual direction shift as mentioned above.

The optical polarizer 31 is pivotable around an axis 32 which may coincide with an optical axis of the optical apparatus OA. Such pivot movement is driven by a drive unit 33 of the optical polarizer 31. Such drive unit 33 is in signal connection with a main control unit CU of the lithographic apparatus LA (cf. FIG. 1). With the control unit CU, a desired linear polarization state of the illumination light 19 path in the polarizer 31 can be achieved.

Via the controllable optical polarizer 31 and the measurement scheme described above, with the sensor device 4a, a polarization dependent measurement of the optical properties of the optical apparatus OA, and for example determination of a diattenuation of the optical system, for example of the illumination system IL and the projection system PS, is possible.

Such diattenuation measurement not necessarily involves the illumination pupil 1 having the plurality of pupil spots 21. Alternatively, such diattenuation measurement also is possible by using a conventional pupil with homogenous intensity of the illumination light 19 across the illumination pupil 1.

A measurement of optical properties of the optical system, for example a measurement of the apodisation properties of the illumination system IL and/or the projection system PS further is possible by use of a Ronchi grating. Details of a principle measurement method using such Ronchi grating can be found in J. Braat et al. “Improved Ronchi test with extended source”, J. Opt. Soc. Am. A, Vol. 16, No. 1, pp. 131-140 (1999) and in US 2002/0145717 A1.

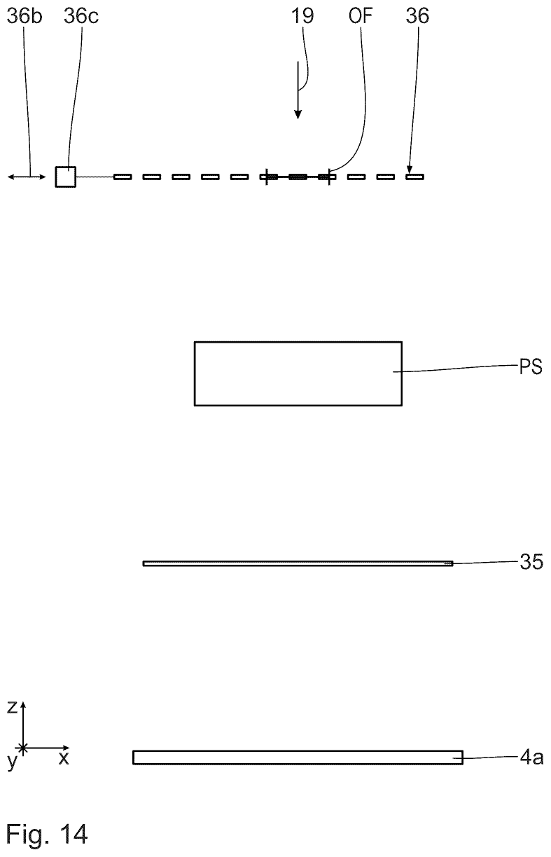

Use of a Ronchi grating in a Ronchi test method of determination of properties of the optical system and the respectively equipped optical apparatus are further discussed with reference to FIGS. 14 to 20.

FIG. 14 schematically shows a sequence of optical elements between an object plane wherein an object field OF is arranged, and the sensor device 4a. Components and functions which correspond to those already discussed above with respect to FIGS. 1 to 13 show the same reference numerals and are not discussed in detail again.

In the object plane, a linear grating 36 is arranged having a plurality of parallel linear grating structures to diffract the illumination light 19. Such grating structures extend perpendicular to the drawing plane of the schematic depiction of FIG. 14. In the FIG. 14 embodiment such linear structures of the linear grating 36 extend along the y-direction. This linear grating 36 serves as a source grating of the Ronchi measurement scheme.

In the beam path of the illumination light 19 downwards to the linear grating 36 is the projection system PS.

A Ronchi grating 35 is arranged between the projection system PS and the sensor device 4a in the beam path of the illumination light 19.

The linear grating 36 is connected to a phase stepping actor 36c to translate the linear grating 36 in a shearing direction perpendicular to its linear structures as indicated in FIG. 14 by a double arrow 36b.

The Ronchi grating 35 is embodied as a checker board configuration having a two-dimensional array of grating structures in both directions x and y.

The sensor device 4a has an array of sensor pixels arranged in an xy plane of FIG. 14.

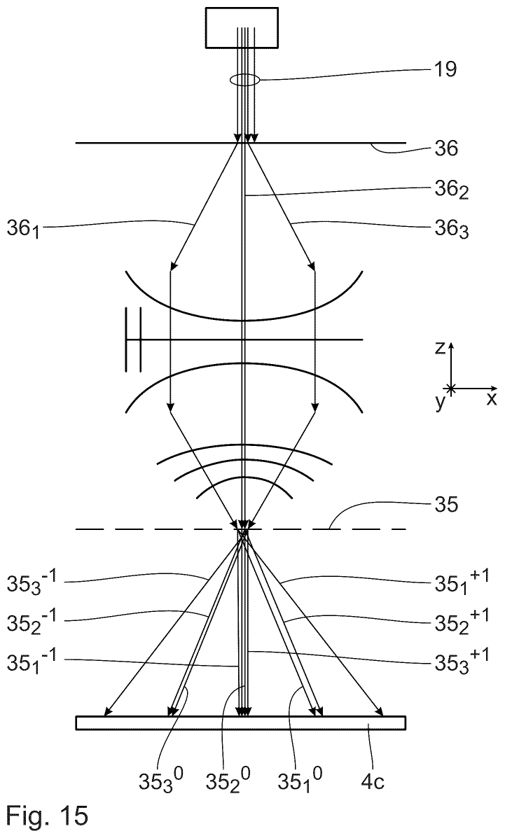

FIG. 15 shows the measurement principle of the FIG. 14 arrangement:

When the linear grating 36 is stepped through the x-direction in FIG. 15, the incoming illumination light 19 is deflected, depending on the stepping phase within one period of the linear grating into linear grating diffraction directions 36₁, 36₂ and 36₃, subsequently.

The Ronchi grating 35 further splits those incoming linear grating diffraction direction 36₁ into Ronchi grating diffraction orders 35₁⁺¹, 35₁⁰, 35₁⁻¹. The linear grating diffraction direction 36₂ is diffracted by the Ronchi grating into Ronchi grating diffraction orders 35₂⁺¹, 35₂⁰, 35₂⁻¹. The linear grating diffraction direction 36₃ is diffracted by the Ronchi grating 35 into Ronchi grating diffraction orders 35₃⁺¹, 35₃⁰, 35₃⁻¹.

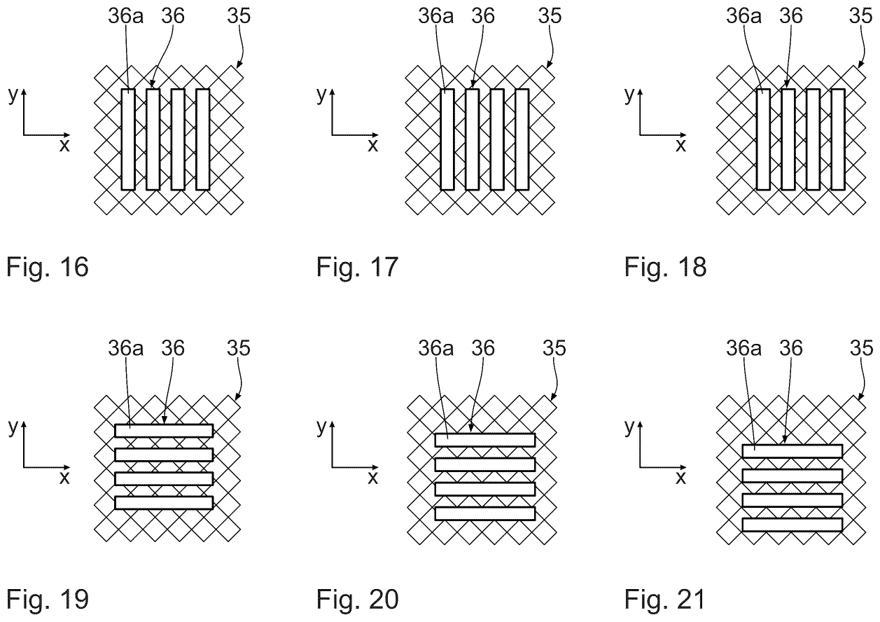

FIGS. 16 to 21 show in a projection along the z direction a superposition, i.e., a xy-position relationship, of the grating structures of the linear grating 36 of a respective area of the optical element 3 on the one hand, and of the checker board arrangement of the Ronchi grating 35 on the other.

FIG. 16 shows the xy position relationship between the grating structures of the linear grating 36 extending along the y direction and the Ronchi grating 35 leading to the linear grating diffraction direction 36₁ in FIG. 15.

FIG. 17 shows the respective relative position of the linear direction 36 and the Ronchi grating 35 resulting in the linear grating diffraction direction 36₂.

FIG. 18 shows the respective relative position of the linear grating 36 and the Ronchi grating 35 resulting in the linear grating diffraction direction 36₃.

FIGS. 19 to 21 show the respective positional xy relationship between linear grating structures 36 of the linear grating 36 extending in the x direction and the Ronchi grating leading, as a result of getting the linear grating 36 along the y-direction in FIGS. 19 to 21 to diffraction orders spread accordingly as the linear diffraction directions 36₁, 36₂, 36₃ explained above with respect to FIG. 15 but now spread in the yz-plane.

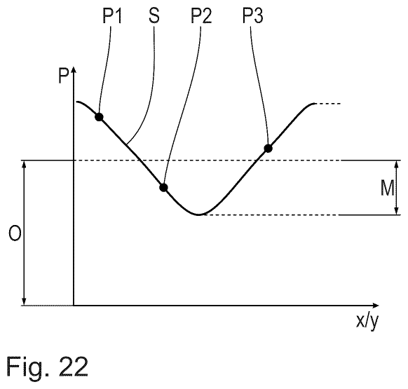

FIG. 22 shows intensity measurement results of a respective Ronchi test with the relative lateral orientations according to FIGS. 16 to 18, i.e., along a first shear direction x. FIG. 22 also is representative for the results of the relative lateral positions according to FIGS. 19 to 21 along the second shear direction y. FIG. 22 shows the intensity measured by exactly one pixel of the sensor device 4a during the relative shearing movement of the linear grating 36 with respect to the Ronchi grating 35 along the x- or y-direction. P1, P2 and P3 correspond to the intensity measurement result of this sensor pixel at three different shearing positions. The number of measurement points Pi may vary and may be larger than three or alternatively may be much larger than three to improve the measurement accurateness.

For each pixel of the sensor device 4a a corresponding phase curve can be fitted, resulting in an accurate phase detection.

Such Ronchi measurement scheme may be performed without wedge structures like the wedges 5 on the optical element 3.

The measurement points P1 to P3 give the full information regarding the course of an expected sine signal S, i.e., its modulation M, its offset O and its phase P. From these data, using the Ronchi test algorithm, the apodisation properties of the optical system including the illumination system IL and the projection system PS can be obtained. For example, the offset O is used to determine an apodisation of the projection system PS in case of an entire apodisation measurement sequence using a linear grating sheared in the x-direction and in the y-direction as explained above.

It will be appreciated that aspects of the present disclosure can be implemented in any convenient way including by way of suitable hardware and/or software. For example, a device arranged to implement the present disclosure may be created using appropriate hardware components. Alternatively, a programmable device may be programmed to implement embodiments of the present disclosure. The present disclosure therefore also provides suitable computer programs for implementing aspects of the present disclosure. Such computer programs can be carried on suitable carrier media including tangible carrier media (e.g., hard disks, CD ROMs and so on) and intangible carrier media such as communications signals.

While specific embodiments of the present disclosure have been described above, it will be appreciated that the present disclosure may be practiced otherwise than as described. The disclosure is not intended to limited by virtue of specific embodiments disclosed herein.

What is claimed is:

1. A method of determining optical properties of an optical system, the optical system comprising an illumination system and a projection system, the method comprising:
providing an illumination of an object field of the optical system via an illumination pupil comprising a plurality of pupil spots;
providing an optical element with an optical surface comprising a plurality of shifting optical areas which effect an individual direction shift, depending on a respective shifting optical area of an illumination beam entering the respective shifting optical area;
calibrating the individual direction shift by measuring a pupil spot shift resulting from the shifting optical areas via a measuring pupil in the illumination beam path after the optical element for each of the pupil spots for a plurality of separate field points within the object field; and
calculating the optical properties to be determined from a measurement using the calibrated individual direction shift.

2. The method of claim 1, wherein the optical element comprises at least one non-shifting optical area which does not impose a direction shift of the illumination beam entering the non-shifting optical area, and wherein a reference illumination beam entering the non-shifting optical area is measured during the calibrating step.

3. The method of claim 1, wherein the shifting optical areas comprises a plurality of wedges with different wedge orientations.

4. The method of claim 3, wherein an angle between different adjacent orientations of the wedges differs by an integer multiple of 45°.

5. The method of claim 1, wherein the plurality of pupil spots of the illumination pupil is arranged as a grid.

6. The method of claim 1, wherein, during calibration, a map is created in which the respective pupil spot shift is attributed to the respective pupil spot and to the respective field point.

7. The method of claim 1, wherein the optical element comprises an optical grating area imposing a diffraction of an illumination beam entering the optical grating area and further passing one of the shifting optical areas of the optical element, wherein the method includes a Ronchi test to obtain the optical property to be determined.

8. The method of claim 1, wherein the optical system comprises an optical polarizer imposing a polarization of an illumination beam entering the shifting optical area, an analyzer the optical polarizer being used to determine a transmission of the optical element for two different polarization states of the illumination beam, and the method comprising: measuring the transmission data; and from the measured transmission data, obtaining a diattenuation of the optical system.

9. The method of claim 8, wherein, while measuring the transmission data, an additional optical analyzer is used to determine the transmission of the optical element for two different polarization states of the illumination beam.

10. The method of claim 1, wherein:
the optical element comprises at least one non-shifting optical area which does not impose a direction shift of the illumination beam entering the non-shifting optical area;
a reference illumination beam entering the non-shifting optical area is measured during the calibrating step; and
the shifting optical areas comprises a plurality of wedges with different wedge orientations.

11. The method of claim 1, further comprising imaging the object field into an image field via the projection objective.

12. One or more machine-readable hardware storage devices comprising instructions that are executable by one or more processing devices to perform operations comprising the method of claim 1.

13. A system, comprising:
one or more processing devices; and
one or more machine-readable hardware storage devices comprising instructions that are executable by the one or more processing devices to perform operations comprising the method of claim 1.

14. The system of claim 13, further comprising:
an optical system, comprising:
a light source configured to provide an illumination beam;
an illumination system configured to illuminate an object field with the illumination beam, the illumination system comprising:
a pupil generating device configured to provide an illumination of the object field via an illumination pupil comprising a plurality of pupil spots; and
a projection system configured to image the object field into an image field;
an optical element comprising an optical surface which comprises a plurality of shifting optical areas configured to effect an individual directing shift depending on a respective shifting optical area of the illumination beam entering the respective shifting optical area; and
a sensor configured to measure a pupil spot shift resulting from the different shifting optical areas via a measuring pupil in the illumination beam path after the optical element for each of the pupil spots for a plurality of separate field points within the object field.

15. An optical apparatus, comprising:
an optical system, comprising:
a light source configured to provide an illumination beam;
an illumination system configured to illuminate an object field with the illumination beam, the illumination system comprising:
a pupil generating device configured to provide an illumination of the object field via an illumination pupil comprising a plurality of pupil spots;
a projection system configured to image the object field into an image field;
an optical element comprising an optical surface which comprises a plurality of shifting optical areas configured to effect an individual directing shift depending on a respective shifting optical area of the illumination beam entering the respective shifting optical area; and
a sensor configured to measure a pupil spot shift resulting from the different shifting optical areas via a measuring pupil in the illumination beam path after the optical element for each of the pupil spots for a plurality of separate field points within the object field.

16. The optical apparatus of claim 15, further comprising a calibration module configured to calibrate the individual direction shift, wherein the calibration module is in signal connection with the sensor device.

17. The optical apparatus of claim 16, further a calculation module configured to calculate optical properties of the optical system from pupil measurement data using the calibrated individual direction shift, wherein the calculation module is in signal connection with the sensor device and the calibration module.

18. The optical apparatus of claim 15, wherein the optical element comprises a Ronchi grating.

19. The optical apparatus of claim 15, further comprising an optical polarizer configured to polarize the illumination beam entering the optical element.

20. The optical apparatus of claim 14, further comprising an optical analyzer to determine a transmission of the optical element for two different polarisation states of the illumination beam.
